(19) United States
(12) Patent Application Publication
(10) Pub. No.: US 2024/0282552 A1
(43) Pub. Date: Aug. 22, 2024

(54) PULSING POWER SUPPLY WITH POWERED CROWBAR

(71) Applicant: EHT Ventures LLC, Seattle, WA (US)

(72) Inventors: Kenneth Miller, Seattle, WA (US); Alex Henson, Seattle, WA (US); James Prager, Seattle, WA (US); Jacob Hagen, Seattle, WA (US)

(21) Appl. No.: 18/440,956

(22) Filed: Feb. 13, 2024

Related U.S. Application Data
(60) Provisional application No. 63/485,536, filed on Feb. 17, 2023.

(51) Int. Cl. H01J 37/32

(52) U.S. Cl. CPC H01J 37/32146; H01J 37/32027; H01J 37/32155; H01J 37/32577

(57) ABSTRACT

A pulsing power supply is disclosed. The pulsing power supply includes a pulser having an output that outputs pulses greater than 5 kV with a pulse repetition frequency greater than 10 kHz; a powered crowbar circuit electrically coupled across the output, the powered crowbar circuit including a DC source, wherein a polarity of the DC power supply is arranged opposite a polarity of the pulser; a transformer having a primary side and a secondary side, the primary side of the transformer is electrically coupled across the output of the pulser and across the powered crowbar circuit; and a plurality of electrodes electrically coupled with the secondary-side of the transformer.

### BACKGROUND

High voltage pulsing power supplies with fast pulse repetition frequencies have many applications in semiconductors processing, medical devices, fusion, green energy, chemical processing, plasma devices, etc. The combination of high voltages and fast pulse repetition frequencies can be difficult. For example, capacitors can be charged to high voltages and the time it takes to discharge these capacitors can limit the pulse repetition frequency. As another example, transformers can also take some time to deflux. This deflux time, can limit the pulse repetition frequency.

### SUMMARY

In some aspects, the techniques described in this document relate to a pulsing power supply system including: a pulser having an output that outputs pulses greater than 5 kV with a pulse repetition frequency greater than 10 kHz; a powered crowbar circuit electrically coupled across the output, the powered crowbar circuit includes a DC source and a diode arranged in series, a polarity of the DC source is arranged opposite a polarity of the pulser; a transformer having a primary side and a secondary side, the primary side of the transformer is electrically coupled across the output of the pulser and across the powered crowbar circuit; and a one or more electrodes electrically coupled with the secondary-side of the transformer.

In some aspects, the techniques described in this document relate to a pulsing power supply system, further including one or more diodes electrically coupled with respective ones of the one or more electrodes.

In some aspects, the techniques described in this document relate to a pulsing power supply system, further including: a second pulser having a second output that outputs pulses greater than 5 kV with a pulse repetition frequency greater than 10 kHz; a second powered crowbar circuit electrically coupled across the second output, the second powered crowbar circuit including a DC source; a second transformer having a primary side and a secondary side, the primary side of the second transformer is electrically coupled across the output of the second pulser and across the second powered crowbar circuit; and a second one or more electrodes electrically coupled with the secondary-side of the second transformer.

In some aspects, the techniques described in this document relate to a pulsing power supply, wherein the inductance of the powered crowbar circuit is less than about 100 nH.

In some aspects, the techniques described in this document relate to a pulsing power supply, wherein the pulser outputs pulses with a voltage V1, a pulse width of T1, and a pulse turn off time of T2, and the voltage of the DC source outputs a voltage V2, wherein.

In some aspects, the techniques described in this document relate to a pulsing power supply, wherein the DC source includes an energy storage capacitor and a DC power supply.

In some aspects, the techniques described in this document relate to a pulsing power supply, further including an energy recovery circuit electrically coupled with the powered crowbar circuit and a DC power source of the pulser.

In some aspects, the techniques described in this document relate to a pulsing power supply including: a pulser having an output that outputs pulses greater than 5 kV with a pulse repetition frequency greater than 10 kHz; a transformer having a primary side and a secondary side, the secondary-side having a first end and a second end; and a powered crowbar circuit electrically coupled across the output of the pulser and across the primary side of the transformer, the powered crowbar circuit including: a DC source; and a crowbar diode having an anode.

In some aspects, the techniques described in this document relate to a pulsing power supply, wherein a polarity of the DC source is arranged opposite a polarity of the pulser.

In some aspects, the techniques described in this document relate to a pulsing power supply, wherein the inductance of the powered crowbar circuit is less than about 100 nH.

In some aspects, the techniques described in this document relate to a pulsing power supply, wherein the pulser outputs pulses with a voltage V1, a pulse width of T1, and a pulse turn off time of T2, and the voltage of the DC source outputs a voltage V2, wherein.

In some aspects, the techniques described in this document relate to a pulsing power supply, wherein the DC source includes an energy storage capacitor and a DC power supply.

In some aspects, the techniques described in this document relate to a pulsing power supply, further including a first secondary-side diode electrically coupled with the first end of the secondary-side of the transformer.

In some aspects, the techniques described in this document relate to a pulsing power supply, further including an electrode electrically coupled with the first secondary-side diode.

In some aspects, the techniques described in this document relate to a pulsing power supply, further including a secondary-side diode electrically coupled with the second end of the secondary-side of the transformer, the secondary-side diode has a polarity opposite a polarity of the first secondary-side diode.

In some aspects, the techniques described in this document relate to a pulsing power supply, further including a second electrode electrically coupled with the secondary-side diode.

In some aspects, the techniques described in this document relate to a pulsing power supply, further including an energy recovery circuit electrically coupled with the powered crowbar circuit and a DC power source of the pulser.

In some aspects, the techniques described in this document relate to a pulsing power supply including: a pulser having an output with a voltage V1 that outputs pulses with a voltage greater than 5 kV, a pulse width of T1, and a pulse turn off time of T2; a powered crowbar circuit electrically coupled across the output, the powered crowbar circuit including a DC source having a voltage V2; and a transformer having a primary side and a secondary side, the primary side of the transformer is electrically coupled across the output of the pulser and across the powered crowbar circuit; wherein

In some aspects, the techniques described in this document relate to a pulsing power supply, wherein the inductance of the powered crowbar circuit is less than about 100 nH.

In some aspects, the techniques described in this document relate to a pulsing power supply, wherein the powered crowbar circuit includes: a capacitor arranged across the DC source; and a crowbar diode having an anode electrically coupled with the pulser.

In some aspects, the techniques described in this document relate to a pulsing power supply, further including: a first plurality of electrodes electrically coupled with the secondary-side of the first transformer; and a second plurality of electrodes electrically coupled with the secondary-side of the second transformer.

In some aspects, the techniques described in this document relate to a pulsing power supply, wherein a polarity of the DC source is arranged opposite a polarity of the pulser.

In some aspects, the techniques described in this document relate to a pulsing power supply, wherein the DC source includes an energy storage capacitor and a DC power supply.

In some aspects, the techniques described in this document relate to a pulsing power supply, further including an energy recovery circuit electrically coupled with the powered crowbar circuit and a DC power source of the pulser.

### BRIEF DESCRIPTION OF THE FIGURES

FIG. 1 is an example circuit diagram of a pulsing power supply system.

FIG. 2A shows an example voltage waveform at a transformer using the pulsing power supply system.

FIG. 2B shows an example voltage waveform at a transformer using the pulsing power supply system.

FIG. 3 is an example circuit diagram of a pulsing power supply system.

FIG. 4 is an example diagram of waveforms.

FIG. 5 is an example diagram of waveforms.

FIG. 6 is an example diagram of waveforms.

FIG. 7 is an example diagram of waveforms.

FIG. 8 is an example diagram of waveforms.

FIG. 9 is an example circuit diagram of a pulsing power supply system with a load.

FIG. 10 is an example circuit diagram of a pulsing power supply system with an energy recovery circuit.

### DETAILED DESCRIPTION

Examples of a pulsing power supply with a transformer are disclosed that can provide both positive and negative pulses to a load (or one or more electrodes) at high voltage and high frequencies.

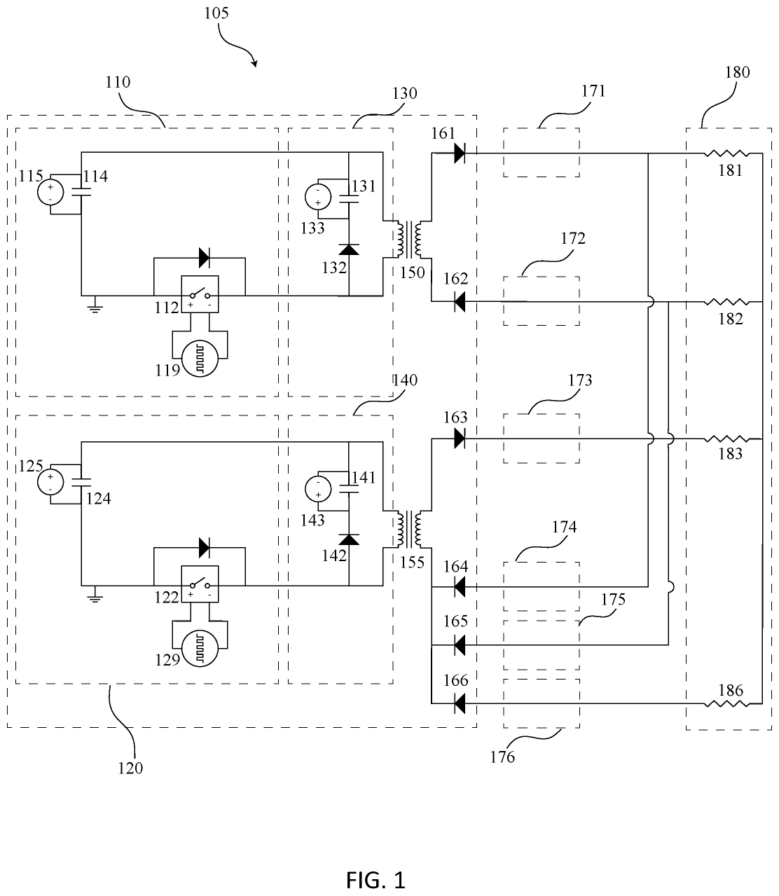

FIG. 1 is an example circuit diagram of a pulsing power supply system 105 coupled with one or more electrodes (e.g., electrode 171, 172, 173, 174, or load 910). The electrodes may be used in any number of ways such as, for example, inserted into, placed on, disposed on, coupled with, attached to a sample 180. The sample 180 may include an organ, a solution, blood, a body, skin, muscle, tissue, chamber, a brain, a breast, etc. The sample 180 may have an inherent resistance represented by resistors 181, 182, 183, 184.

The sample 180 may also include plasma in a plasma chamber, a reactor chamber in a chemical processing system, or any other system that includes one or more electrodes.

In some applications, the electrodes may be used for electroporation or ablation. In some applications, the electrodes may be part of a catheter, patch, etc. In some applications, the electrodes may be part of a plasma chamber, a reaction chamber, etc.

The pulsing power supply system 105, in this example, includes a first pulser 110 electrically coupled with a first powered crowbar circuit 130 and a transformer 150. In this example, the pulsing power supply system 105 includes a second pulser 120 electrically coupled with a second powered crowbar circuit 140 and a second transformer 155. The second pulser 120 is not required.

A pulser (e.g., the first pulser 110 and/or the second pulser 120), for example, can produce a plurality of high voltage pulses with a high pulse repetition frequency, fast rise times, and/or fast fall times. A pulser (e.g., all of the circuits shown in the drawings, the first pulser 110, and/or the second pulser 120), for example, may comprise a nanosecond pulser. A pulser may include all or part of a pulser disclosed in U.S. Pat. No. 9,960,763 titled “High Voltage Nanosecond pulser”, U.S. Pat. No. 10,734,906, titled “Nanosecond Pulser”, or U.S. Pat. No. 10,020,800 titled “High Voltage nanosecond Pulser with Variable Pulse Width and Pulse Repetition Frequency.”

High voltage pulses, for example, may include pulses with any or all the following specifications: a frequency range of 1 kHz to 10 MHz, a pulse width range of 10 ns to 10 s, a rise time (and/or a fall time) of 1 ns to 100 μs, a duty cycle between 0 and 100%, a flat top ripple range between 0 and 200%, and/or an output voltage of more than 1 kV, 2 kV, 5 kV, 10 kV, 30 kV, 100 kV, 300 kV, 1,000 kV. High voltage pulses, for example, may include pulses with a rise time of less than 10 μs (or a rise time less than 1 μs), an output voltage greater than 1 kV, and/or a ripple between 2% and 50%.

A high voltage pulse may include non-sinusoidal pulses. A high voltage pulse may not have a sinusoidal shape. A high voltage pulse may include a fast rising voltage spike followed by a fast fall. A high voltage pulse may include a positive going pulse portion and a secondary pulse portion.

The first pulser 110, for example, can include a first switch module 112 with one or more solid state switches (e.g., IGBTs, a MOSFETs, a SiC MOSFETs, SiC junction transistors, FETs, SiC switches, GaN switches, photoconductive switches, etc.). One or more solid state switches and or circuits can be arranged in parallel or series. The first switch module 112, for example, may be coupled with a DC source that may include, for example, an energy storage capacitor 114 coupled with a DC power supply 115. The first switch module 112, for example, may be opened or closed based on timing signals from control source 119.

The second pulser 120, for example, can include a second switch module 122 with one or more solid state switches (e.g., IGBTs, a MOSFETs, a SiC MOSFETs, SiC junction transistors, FETs, SiC switches, GaN switches, photoconductive switches, etc.). One or more solid state switches and or circuits can be arranged in parallel or series. The second switch module 122 may be coupled with a DC source such as, for example, an energy storage capacitor 124 coupled with a DC power supply 125. The switch module 122, for example, may be opened or closed based on timing signals from control source 129, which may or may not be different from the timing provided to second switch module 122 provided by control source 129.

The first powered crowbar circuit 130, for example, may be disposed across the output of the first pulser 110. The first powered crowbar circuit 130, for example, may be disposed across the primary windings of the transformer 150. The first powered crowbar circuit 130, for example, may include a DC power supply 133, a crowbar diode 132 and an energy storage capacitor 131. The anode of the crowbar diode 132 may be electrically coupled with the collector of the first switch module 112 and the cathode of the crowbar diode 132 may be electrically coupled with the energy storage capacitor 131. The energy storage capacitor 131, for example, may have a capacitance of about 100 nF, 1 μF, 10 μF, 100 μF, 1 mF or more. The first powered crowbar circuit 130 may have a low inductance such as, for example, an inductance less than about 100 nH.

The energy storage capacitor 131, for example, may be coupled across the DC power supply 133. The DC power supply 133 may provide a voltage or charge to the energy storage capacitor 131 that blocks return current that may flow from the sample 180 through second electrode 172 back to the first pulser 110. In one example, the DC power supply 133 may provide a voltage that is less than (e.g., about one half) the voltage provided by the DC power supply 115 or less than (e.g., about one half) about half the voltage amplitude of the pulses produced by the first pulser 110. As another example, the DC power supply 133 may have a polarity that is opposite the polarity of the first pulser 110 or the DC power supply 125.

The first pulser 110 may be electrically coupled with a first transformer 150. The first transformer 150 may be electrically coupled across the output of the first pulser 110 and across the first powered crowbar circuit 130.

The first transformer 150, for example, may have a plurality of primary windings wound around a core and on or more secondary winding wound around the core. The output of the first pulser 110 may be coupled with the primary windings of the first transformer 150. The secondary winding of the first transformer 150 may have a positive end and a negative end. The anode of a first secondary-side diode 161 may be electrically coupled with the positive end of the secondary winding. The cathode of a second diode 162 may be electrically coupled with the negative end of the secondary winding.

The first electrode 171 may be electrically coupled with the cathode of the first secondary-side diode 161. The second electrode 172 may be electrically coupled the anode of the second diode 162. In operation, the charges present on the first electrode 171 and the second electrode 172 may have opposite polarities.

The second powered crowbar circuit 140, for example, may be disposed across the output of the second pulser 120. The second powered crowbar circuit 140, for example, may be disposed across the primary windings of the second transformer 155. The second powered crowbar circuit 140, for example, may include a DC power supply 143, a crowbar diode 142, and an energy storage capacitor 141 arranged in series. The anode of the diode 142 may be electrically coupled with the collector of the second switch module 122 and the cathode of the crowbar diode 142 may be electrically coupled with the energy storage capacitor 141. The energy storage capacitor 141, for example, may have a capacitance of about 100 nF, 1 μF, 10 μF, 100 μF, 1 mF or more. The second powered crowbar circuit 130 may have a low inductance such as, for example, an inductance less than about 100 nH.

The energy storage capacitor 141, for example, may be coupled across the DC power supply 143. The DC power supply 143 may provide a voltage to the energy storage capacitor 141 that blocks return current that may flow from the sample 180 through the third electrode 173 and/or the fourth electrode 174 back to the second transformer 155. In one example, the DC power supply 143 may provide a voltage that is less than (e.g., about one half) the voltage provided by the DC power supply 125. In another example, the DC power supply 143 may provide a voltage that is about equal to the voltage provided by the energy storage capacitor 124. As another example, the DC power supply 133 may have a polarity that is opposite the polarity of the first pulser 110 or the DC power supply 125.

The second pulser 120 may be electrically coupled with a second transformer 155. The second transformer 155 may be electrically coupled across the output of the second pulser 120 and across the second powered crowbar circuit 140.

The second transformer 155, for example, may have a plurality of primary windings wound around a core and plurality of secondary winding wound around the core. The output of the second pulser 120 may be coupled with the plurality of primary windings. The secondary winding may have a first end and a second end.

The third electrode 173 may be electrically coupled with the first end of the secondary winding of the second transformer 155 such as, for example, the anode of the third electrode 173 may be coupled with first end of the secondary winding of the second transformer 155. The fourth electrode 174 may be electrically coupled with the second end of the secondary winding of the second transformer 155 such as, for example, the cathode of the fourth electrode 174 may be coupled with second end of the secondary winding of the second transformer 155.

Each electrode of the plurality of the electrodes may be coupled with a diode of the power supply system that allows current to flow in one direction into and out of the sample 180 through. Some of the electrodes of the plurality of the electrodes may be coupled with a diode with a different polarity than the other diodes.

The third secondary-side diode 163 is coupled with a first end of the second transformer 155. The third secondary-side diode 163, for example, may also be coupled with the third electrode 173. The third secondary-side diode 163, for example, may have the same polarity as first secondary-side diode 161. The third secondary-side diode 163, for example, may have a polarity that allows current to flow from the first transformer 150 to the sample 180 via first electrode 171.

In this example, the fourth secondary-side diode 164 may be coupled with a second end of the second transformer 155. The fourth secondary-side diode 164 may, for example, may be coupled with first electrode 171. The fourth secondary-side diode 164 may, for example, have a polarity that is the same as the second diode 162. The fourth secondary-side diode 164, for example, may allow current to flow from sample 180 via first electrode 171 to the second transformer 155 as the second transformer 155 defluxes.

The fifth secondary-side diode 165 is coupled with a second end of the second transformer 155. The fifth secondary-side diode 165 may, for example, have a polarity that is opposite the polarity of the third secondary-side diode 163. The fifth secondary-side diode 165 may, for example, have a polarity that is the same as the second diode 162. The fifth secondary-side diode 165 may, for example, allow current to flow from sample 180 via second electrode 172 to the second transformer 155 as the second transformer 155 defluxes.

The sixth secondary-side diode 166 is coupled with a second end of the second transformer 155. The sixth secondary-side diode 166, for example, may also be coupled with the fourth electrode 174. The sixth secondary-side diode 166 may, for example, have a polarity that is opposite the polarity of the third secondary-side diode 163. The sixth secondary-side diode 166 may, for example, have a polarity that is the same as the second diode 162. The sixth secondary-side diode 166 may, for example, allow current to flow from sample 180 via the fourth electrode 174 to the second transformer 155 as the second transformer 155 defluxes.

Each electrode of the plurality of the electrodes, for example, may be coupled together as part of a single catheter. A subset of the electrodes of the plurality of the electrodes, for example, may be coupled together as part of a single catheter. Each electrode of the plurality of the electrodes, for example, may be separate and/or distinct electrodes.

When the first pulser 110 is pulsing, a positive pulse is produced on the first electrode 171 and a negative pulse is produced on the second electrode 172. When the first pulser 110 is pulsing and the second pulser 120 is not pulsing, the second powered crowbar circuit 140, which is coupled with the second pulser 120, may block current from flowing from the first pulser 110, through the sample 180, through the fourth electrode 174, through second transformer 155, and back to the second pulser 120. Instead, a charge may be created across energy storage capacitor 141 by the DC power supply 143 may block current from flowing back into the second pulser 120. The energy storage capacitor 141 and the DC power supply 143 comprise a DC source. The charge created on the energy storage capacitor 141 by the DC power supply 143, for example, may be less than the voltage produced at the first electrode 171.

When the second pulser 120 is pulsing, a positive pulse is produced on the third electrode 173, a negative pulse is produced on the fourth electrode 174. When the second pulser 120 is pulsing and the first pulser 110 is not pulsing, the first powered crowbar circuit 130, which is coupled with the first pulser 110, blocks current from flowing from the second pulser 120, through the sample 180, through the second electrode 172, through transformer 150, and back to the first pulser 110. Instead, a charge created across an energy storage capacitor 131 by the DC power supply 133 may effectively block current from flowing back into the first pulser 110. The energy storage capacitor 131 and the DC power supply 133 comprise a DC source. The charge created on the energy storage capacitor 131 by the DC power supply 133, may be less than the voltage produced at the fourth electrode 174.

A relationship may be established between the voltage produced by the first switch module 112 (V₁), the voltage produced by DC power supply 133 (V₂), the pulse turn on time of the first switch module 112 (T₁), and the pulse turn off time from the first switch module 112 (T₁). The relationship, for example, may be |V₁|T₁≤|V₂|T₂. This may allow, for example, for faster pulse repetition frequencies and/or for positive going pulses followed by negative going pulses.

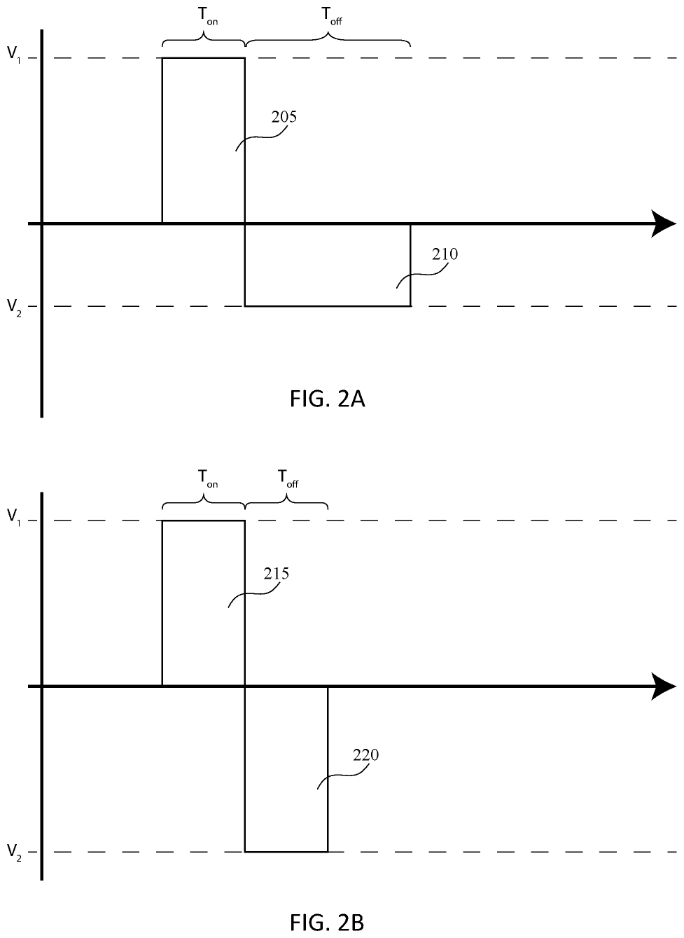

FIG. 2A shows an example first pulse 205 measured on the first transformer 150 during a first pulse using the first pulser 110. The first pulse has a voltage of V₁ on the transformer 150 and a pulse width of T₁. A second pulse 210, which has the opposite polarity as the first pulse, is created by the core of the transformer 150 defluxing from magnetizing current flowing from the first transformer core up the first powered crowbar circuit 130, which creates a negative voltage on the core from the DC power supply 133 resulting in the second pulse 210. The second pulse has a voltage V₂ on the transformer 150 from the DC power supply 133 and a pulse width of t₂. During the second pulse, the voltage V₂ should be set as V₂=−½V₁, and the second pulse width, or the time the pulser is not pulsing, is T₂=−2T₁. In this example, the relationship |V₁|T₁≤|V₂|T₂ holds.

FIG. 2B shows another example first pulse 215 measured on the first transformer 150 during a first pulse using the first pulser 110. A second pulse 220 is created by the core of the transformer defluxing from magnetizing current flowing from the first transformer core up the first powered crowbar circuit 130, which creates a negative voltage on the core from the DC power supply 133 resulting in second pulse 220. During the first pulse, the voltage on the first transformer 150 is V₁ and the pulse width is T₁. During the second pulse, the voltage on the first transformer 150 is the voltage of the DC power supply 133, which in this case is V₂=−V₁, and the pulse width is about the same T₂=−2T₁. Having a higher voltage for the DC power supply 133, for example, allows for a faster pulse repetition frequency and shorter pulse width. In this example, the relationship |V₁|T₁≤|V₂|T₂ holds.

Similar pulses can be created at the second transformer 155 as those shown in FIG. 2A and FIG. 2B. The pulses shown in FIG. 2A and FIG. 2B are not the pulses produced at the electrodes. For instance, the second pulse 210 the second pulse 220 (the negative pulse) in both figures is not produced at the electrodes.

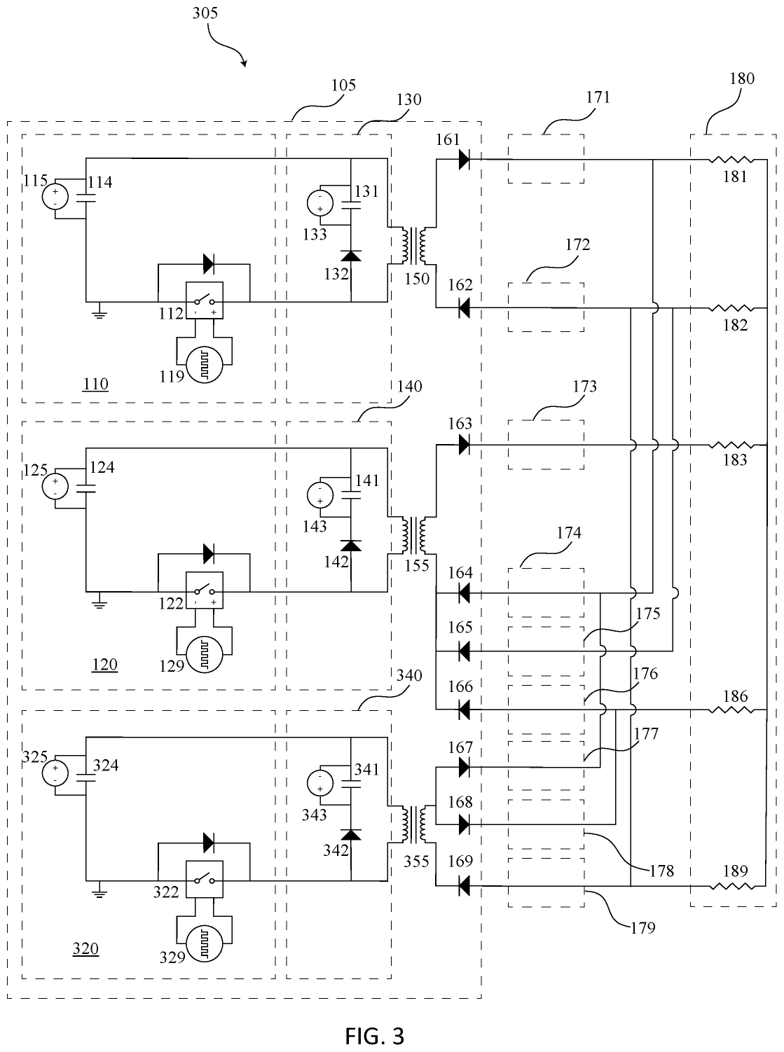

FIG. 3 is an example circuit diagram of a pulsing power supply system 305 coupled with a plurality of the electrodes, 179. In this example, the inherent resistance of the sample 180 may be represented by resistors 181, 182, 183, 184, 185.

The pulsing power supply system 305 includes the first pulser 110, the second pulser 120, and a third pulser 320. The third pulser 320, for example, may have the same or similar components as the first pulser 110 and/or the second pulser 120. The third pulser 320 may be coupled with a third powered crowbar 340 and third transformer 355. The third pulser 320 may be coupled with a third transformer 355.

The third pulser 320, for example, can include a third switch module 322 with one or more solid state switches (e.g., IGBTs, a MOSFETs, a SiC MOSFETs, SiC junction transistors, FETs, SiC switches, GaN switches, photoconductive switches, etc.). One or more solid state switches and or circuits can be arranged in parallel or series. The third switch module 322 may be coupled with a DC source such as, for example, an energy storage capacitor 324 coupled with a power supply 325. The third switch module 322, for example, may be opened or closed based on timing signals from control source 329, which may or may not be different from the timing provided to third switch module 322 provided by control source 329.

The third powered crowbar 340, for example, may be disposed across the output of the third pulser 320. The third powered crowbar 340, for example, may be disposed across the primary windings of the third transformer 355. The third powered crowbar 340, for example, may include crowbar diode 342 and a DC source arranged in series. The DC source may include the energy storage capacitor 341 and the DC power supply 343. The anode of the crowbar diode 342 may be electrically coupled with the cathode of the crowbar diode 342 may be electrically coupled with the diode third switch module 322. The energy storage capacitor 341, for example, may have a capacitance of about 100 nF, 1 μF, 10 μF, 100 μF, 1 mF or more. The third powered crowbar 340 may have a low inductance such as, for example, an inductance less than about 100 nH.

The third pulser 320 may be electrically coupled with a third transformer 355. The third transformer 355 may be electrically coupled across the output of the third pulser 320 and across the third powered crowbar 340.

A first end of the secondary side of the third transformer 355 may be coupled with seventh secondary-side diode 167 and/or with eighth secondary-side diode 168. The polarity of seventh secondary-side diode 167 and/or eighth secondary-side diode 168 may be the same as first secondary-side diode 161 and/or third secondary-side diode 163. The seventh secondary-side diode 167, for example, may be coupled with fourth secondary-side diode 164. The eighth secondary-side diode 168, for example, may be coupled with second diode 162.

The fifth electrode 175 may be electrically coupled with a second end of the secondary winding of the third transformer 355 such as, for example, the fifth electrode 175 may be coupled with second end of the secondary winding of the third transformer 355 via ninth secondary-side diode 169.

When the third pulser 320 is pulsing a negative pulse is produced on the fifth electrode 175. When the third pulser 320 is pulsing and the first pulser 110 is not pulsing, the first powered crowbar circuit 130, which is coupled with the first pulser 110, blocks current from flowing from the third pulser 320, through the sample 180, through the second electrode 172, through the transformer 150, and back to the first pulser 110. Instead, a charge created across the energy storage capacitor 131 by the DC power supply 133, for example, may block current from flowing back into the first pulser 110. The voltage on the energy storage capacitor 131 produced by the DC power supply 133 may be less than the voltage produced at the fourth electrode 174.

When the third pulser 320 is pulsing and the second pulser 120 is not pulsing, the second powered crowbar circuit 140, which is coupled with the second pulser 120, blocks current from flowing from the third pulser 320, through the sample 180, through fourth electrode 174, through the second transformer 155, and back to the second pulser 120. Instead, a charge created across the energy storage capacitor 141 by the DC power supply 143, for example, may block current from flowing back into the second pulser 120. The charge created on the energy storage capacitor 141, by the DC power supply 143, may be less than (e.g., about one half) the voltage produced at the first electrode 171.

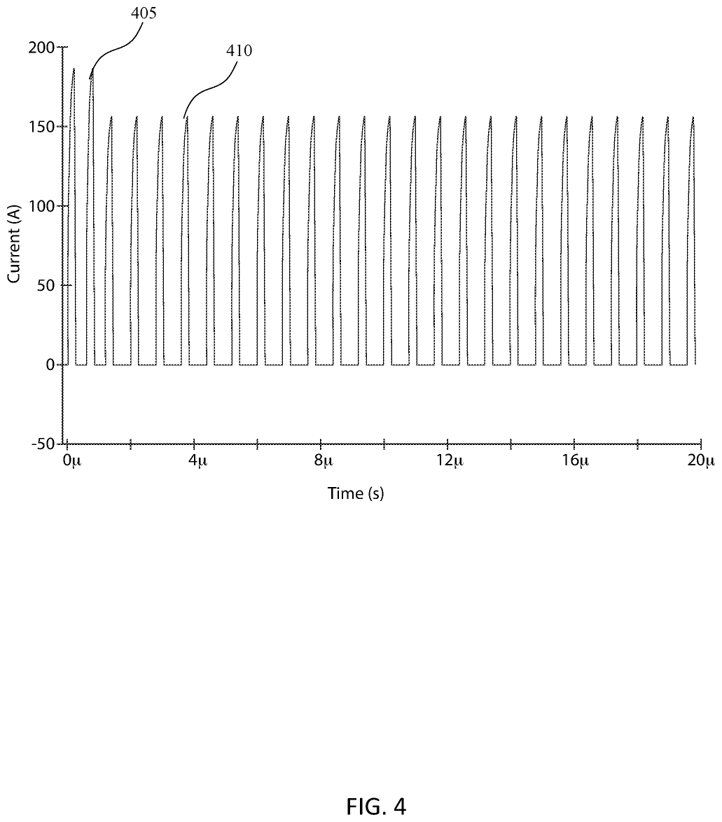

FIGS. 4, 5, 6, 7, and 8 show example waveforms using the pulsing power supply system shown in FIG. 1.

FIG. 4 is an example diagram of a waveform 405 showing the current leaving the first transformer 150 and a waveform 410 showing the current leaving the second transformer 155. In this example, two pulses were created by the first pulser 110 followed by twenty pulses created by the second pulser 120.

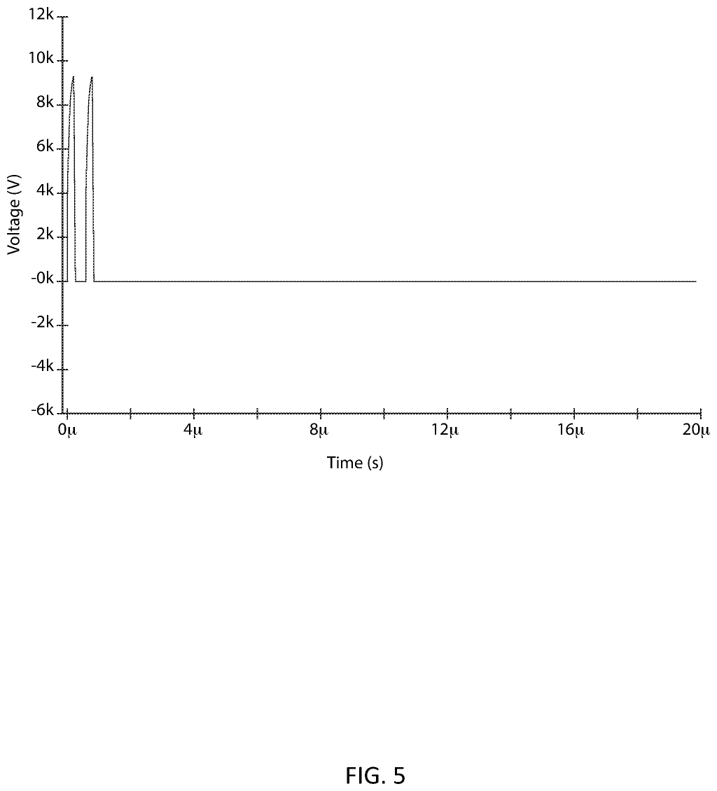

FIG. 5 is an example diagram of a voltage waveform produced at first electrode 171.

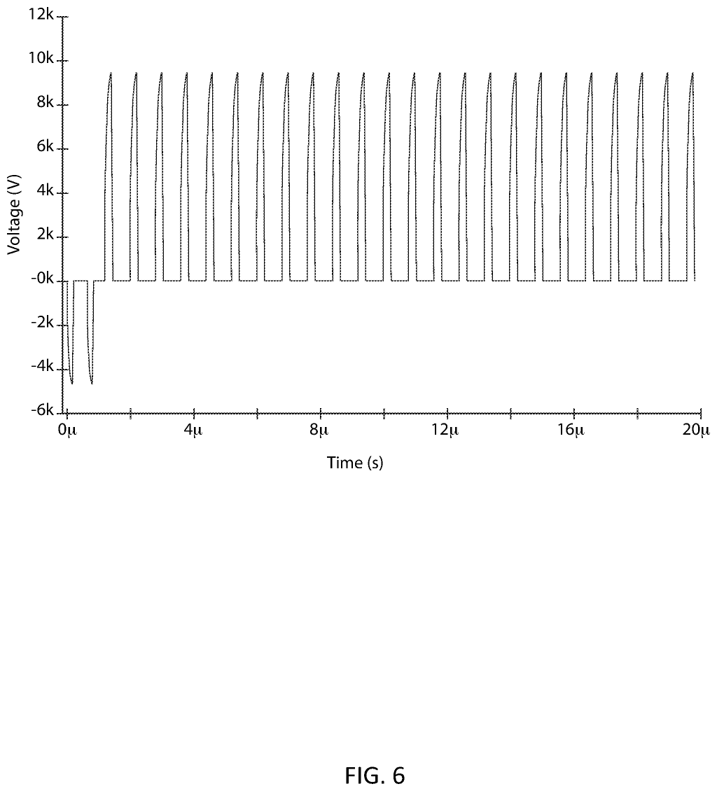

FIG. 6 is an example diagram of a voltage waveform produced at second electrode 172. Note that the negative voltage is produced when the first pulser 110 is pulsing and the positive voltage is produced when the second pulser 120 is pulsing.

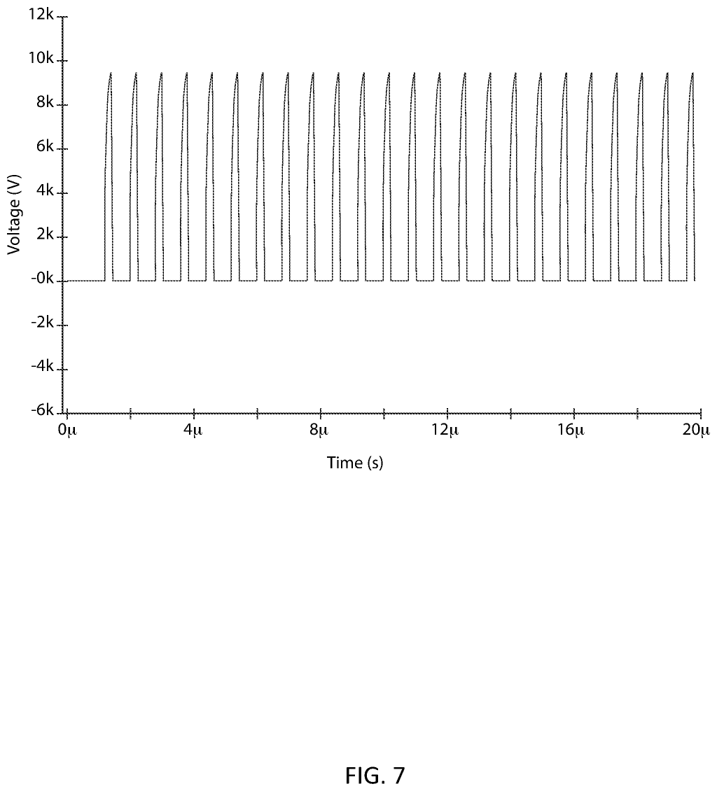

FIG. 7 is an example diagram of a voltage waveform produced at third electrode 173. As shown, no voltage is produced when the first pulser 110 is pulsing.

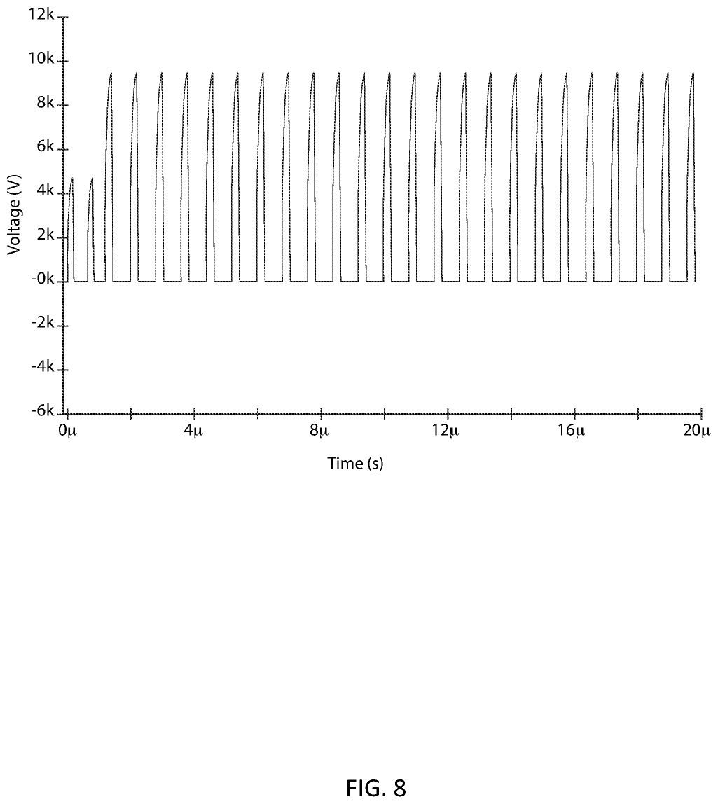

FIG. 8 is an example diagram of a voltage waveform produced at the fourth electrode 174.

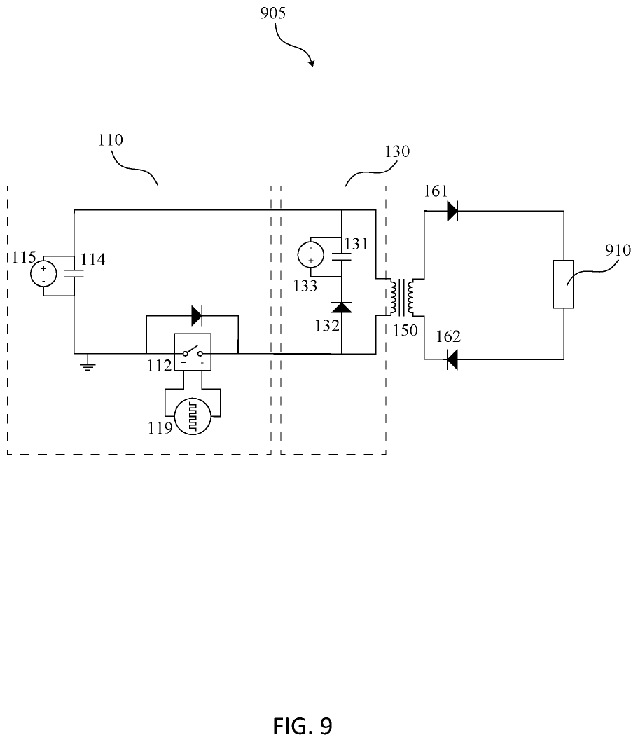

FIG. 9 is an example circuit diagram of a pulsing power supply system 905 with a load 910. In this example, the pulsing power supply system 905 is similar to the pulsing power supply system 105 with the electrodes replaced by a load 910. In this example, the primary side of the first transformer 150 is arranged across both the first pulser 110 and the first powered crowbar circuit 130 as shown and discussed in regard to the pulsing power supply system 105 discussed above in regard to FIG. 1. A load 910 is arranged across the secondary-side of the first transformer 150. The load 910 may include any type of load including, for example, a capacitive load, a resistive load, and/or an inductive load. While first secondary-side diode 161 and second diode 162 are shown, these may or may not be used. The diode 161 and/or second diode 162 may or may not be used.

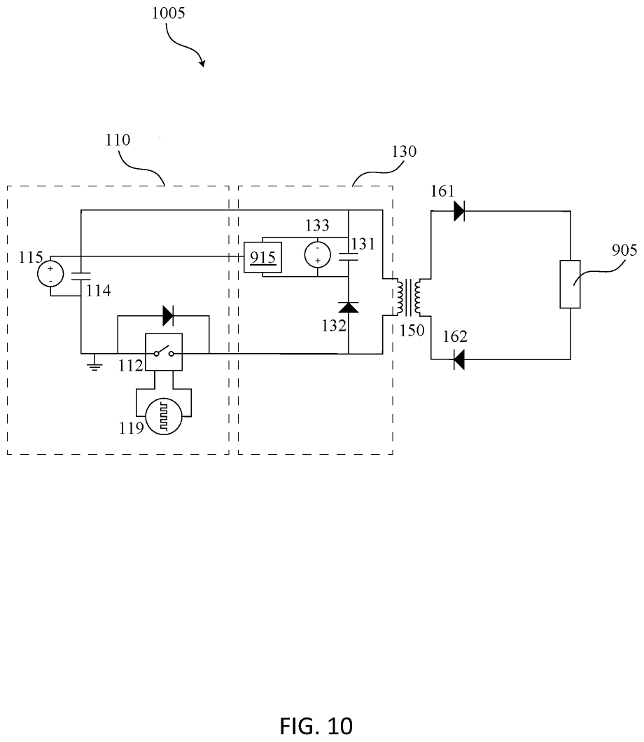

FIG. 10 is an example circuit diagram of a pulsing power supply system 1005 with an energy recovery circuit 915. In this example, the pulsing power supply system is similar to the pulsing power supply system 905 shown in FIG. 9. In this example, the DC power supply 133 is coupled with an energy recovery circuit 915. The energy recovery circuit 915, for example, may include a rectifier, DC converter, and/or one or more diodes. The energy recovery circuit 915, for example, may allow charge on the energy storage capacitor 131 from defluxing the first transformer 150 to charge the energy storage capacitor 114. The diode 161 and/or second diode 162 may or may not be used.

Unless otherwise specified, the term “substantially” means within 5% or 10% of the value referred to or within manufacturing tolerances. Unless otherwise specified, the term “about” means within 5% or 10% of the value referred to or within manufacturing tolerances.

The conjunction “or” is inclusive.

The terms “first”, “second”, “third”, etc. are used to distinguish respective elements and are not used to denote a particular order of those elements unless otherwise specified or order is explicitly described or required.

Numerous specific details are set forth to provide a thorough understanding of the claimed subject matter. However, those skilled in the art will understand that the claimed subject matter may be practiced without these specific details. In other instances, methods, apparatuses or systems that would be known by one of ordinary skill have not been described in detail so as not to obscure claimed subject matter.

Embodiments of the methods disclosed may be performed in the operation of such computing devices. The order of the blocks presented in the examples above can be varied—for example, blocks can be re-ordered, combined, and/or broken into sub-blocks. Certain blocks or processes can be performed in parallel.

The use of “adapted to” or “configured to” is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Headings, lists, and numbering included are for ease of explanation only and are not meant to be limiting.

While the present subject matter has been described in detail with respect to specific embodiments thereof, it will be appreciated that those skilled in the art, upon attaining an understanding of the foregoing, may readily produce alterations to, variations of, and equivalents to such embodiments. Accordingly, it should be understood that the present disclosure has been presented for purposes of example rather than limitation, and does not preclude inclusion of such modifications, variations and/or additions to the present subject matter as would be readily apparent to one of ordinary skill in the art.

That which is claimed:

1. A pulsing power supply system comprising:
a pulser having an output that outputs pulses greater than 5 kV with a pulse repetition frequency greater than 10 kHz;
a powered crowbar circuit electrically coupled across the output, the powered crowbar circuit includes a DC source and a diode arranged in series, a polarity of the DC source is arranged opposite a polarity of the pulser;
a transformer having a primary side and a secondary side, the primary side of the transformer is electrically coupled across the output of the pulser and across the powered crowbar circuit; and
a one or more electrodes electrically coupled with the secondary-side of the transformer.

2. The pulsing power supply system according to claim 1, further comprising one or more diodes electrically coupled with respective ones of the one or more electrodes.

3. The pulsing power supply system according to claim 1, further comprising:
a second pulser having a second output that outputs pulses greater than 5 kV with a pulse repetition frequency greater than 10 kHz;
a second powered crowbar circuit electrically coupled across the second output, the second powered crowbar circuit including a DC source;
a second transformer having a primary side and a secondary side, the primary side of the second transformer is electrically coupled across the output of the second pulser and across the second powered crowbar circuit; and
a second one or more electrodes electrically coupled with the secondary-side of the second transformer.

4. The pulsing power supply according to claim 1, wherein the inductance of the powered crowbar circuit is less than about 100 nH.

5. The pulsing power supply according to claim 1, wherein the pulser outputs pulses with a voltage V₁, a pulse width of T₁, and a pulse turn off time of T₂, and the voltage of the DC source outputs a voltage V₂, wherein |V₁|T₁≤|V₂|T₂.

6. The pulsing power supply according to claim 1, wherein the DC source comprises an energy storage capacitor and a DC power supply.

7. The pulsing power supply according to claim 1, further comprising an energy recovery circuit electrically coupled with the powered crowbar circuit and a DC power source of the pulser.

8. A pulsing power supply comprising:
a pulser having an output that outputs pulses greater than 5 kV with a pulse repetition frequency greater than 10 kHz;
a transformer having a primary side and a secondary side, the secondary-side having a first end and a second end; and
a powered crowbar circuit electrically coupled across the output of the pulser and across the primary side of the transformer, the powered crowbar circuit comprising:
a DC source; and
a crowbar diode having an anode.

9. The pulsing power supply according to claim 8, wherein a polarity of the DC source is arranged opposite a polarity of the pulser.

10. The pulsing power supply according to claim 8, wherein the inductance of the powered crowbar circuit is less than about 100 nH.

11. The pulsing power supply according to claim 8, wherein the pulser outputs pulses with a voltage V₁, a pulse width of T₁, and a pulse turn off time of T₂, and the voltage of the DC source outputs a voltage V₂, wherein |V₁|T₁≤|V₂|T₂.

12. The pulsing power supply according to claim 8, wherein the DC source comprises an energy storage capacitor and a DC power supply.

13. The pulsing power supply according to claim 8, further comprising a first secondary-side diode electrically coupled with the first end of the secondary-side of the transformer.

14. The pulsing power supply according to claim 13, further comprising an electrode electrically coupled with the first secondary-side diode.

15. The pulsing power supply according to claim 13, further comprising a secondary-side diode electrically coupled with the second end of the secondary-side of the transformer, the secondary-side diode has a polarity opposite a polarity of the first secondary-side diode.

16. The pulsing power supply according to claim 15, further comprising a second electrode electrically coupled with the secondary-side diode.

17. The pulsing power supply according to claim 8, further comprising an energy recovery circuit electrically coupled with the powered crowbar circuit and a DC power source of the pulser.

18. A pulsing power supply comprising:
a pulser having an output with a voltage V₁ that outputs pulses with a voltage greater than 5 kV, a pulse width of T₁, and a pulse turn off time of T₂;
a powered crowbar circuit electrically coupled across the output, the powered crowbar circuit including a DC source having a voltage V₂; and
a transformer having a primary side and a secondary side, the primary side of the transformer is electrically coupled across the output of the pulser and across the powered crowbar circuit;
wherein |V₁|T₁≤|V₂|T₂.

19. The pulsing power supply according to claim 18, wherein the inductance of the powered crowbar circuit is less than about 100 nH.

20. The pulsing power supply according to claim 18, wherein the powered crowbar circuit comprises:
a capacitor arranged across the DC source; and
a crowbar diode having an anode electrically coupled with the pulser.

21. The pulsing power supply according to claim 18, further comprising:
a first plurality of electrodes electrically coupled with the secondary-side of the first transformer; and
a second plurality of electrodes electrically coupled with the secondary-side of the second transformer.

22. The pulsing power supply according to claim 18, wherein a polarity of the DC source is arranged opposite a polarity of the pulser.

23. The pulsing power supply according to claim 18, wherein the DC source comprises an energy storage capacitor and a DC power supply.

24. The pulsing power supply according to claim 18, further comprising an energy recovery circuit electrically coupled with the powered crowbar circuit and a DC power source of the pulser.
